(19) United States
(12) Patent Application Publication
(10) Pub. No.: US 2026/0333821 A1
(43) Pub. Date: Oct. 22, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventor: Daichi DANSAKO, Tokyo (JP)

(73) Assignee: Mitsubishi Electric Corporation, Tokyo (JP)

(21) Appl. No.: 19/532,071

(22) Filed: Feb. 6, 2026

(30) Foreign Application Priority Data
Apr. 16, 2025 (JP) 2025-067360

(51) Int. Cl. H10D 64/27; H10D 30/01; H10D 30/66; H10D 62/10; H10D 62/832

(52) U.S. Cl. CPC H10D 64/516; H10D 30/0291; H10D 30/66; H10D 62/106; H10D 62/8325

(57) ABSTRACT

An object of the present disclosure is to provide a semiconductor device capable of reducing parasitic capacitance while suppressing ON resistance. A semiconductor device includes a gate oxide film formed on an n⁺-type well region in a JFET region as a region sandwiched between a plurality of p-type well regions in a plan view and a channel region as a region sandwiched between the JFET region and the source region in a surface layer of each of the p-type well regions and a gate electrode formed on the channel region via the gate oxide film. The gate oxide film includes an oxide film deep portion formed at a deeper position than the gate oxide film on the channel region in the JFET region. The oxide film deep portion has a tapered shape with a narrower width as getting deeper.

### BACKGROUND

### Technical Field

The present disclosure relates to a semiconductor device.

### Description of the Background Art

Japanese Patent Application Laid-Open No. 2009-259861 discloses a technique of forming a trench between p-type base layers adjacent to each other and burying a part of a gate oxide film covering a gate electrode into the trench, thereby reducing parasitic capacitance.

### SUMMARY

In the configuration of Japanese Patent Application Laid-Open No. 2009-259861, a path of current is restricted by the gate oxide film buried in the trench. Thus, the configuration thereof has a problem that ON resistance is increased compared with a general planar-type MOS.

An object of the present disclosure is to provide a semiconductor device capable of reducing parasitic capacitance while suppressing ON resistance.

A semiconductor device according to the present disclosure includes a drift layer of a first conductivity type, a first well region, a plurality of second well regions of a second conductivity type, a gate oxide film, and a gate electrode. The drift layer is formed on a semiconductor substrate of a first conductivity type. The first well region is formed on the drift layer and has a higher impurity concentration of a first conductivity type than the drift layer. The plurality of second well regions are discretely formed on a surface layer of the first well region. An impurity region is formed on a surface layer of each of the plurality of second well regions. The gate oxide film is formed on the first well region in a JFET region as a region sandwiched between the plurality of second well regions in a plan view and a channel region as a region sandwiched between the JFET region and the impurity region in the surface layers of the second well regions. The gate electrode is formed on the channel region via the gate oxide film. The gate oxide film includes at least one oxide film deep portion formed at a deeper position than the gate oxide film on the channel region in the JFET region. The oxide film deep portion has a tapered shape with a narrower width as getting deeper.

The semiconductor device according to the present disclosure reduces parasitic capacitance by the oxide film deep portion as the gate oxide film buried in the first well region in the JFET region. Since the oxide film deep portion has a tapered shape, a current path in a forward direction is not blocked, and increase of ON resistance is suppressed.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a top view of a semiconductor device according to an embodiment 1.

FIG. 2 is a cross-sectional view of the semiconductor device according to the embodiment 1.

FIG. 3 is a cross-sectional view of a semiconductor device according to a first modification example of the embodiment 1.

FIG. 4 is a cross-sectional view of a semiconductor device according to a second modification example of the embodiment 1.

FIG. 5 is a cross-sectional view of a semiconductor device according to a third modification example of the embodiment 1.

FIG. 6 is a top view of the semiconductor device according to the embodiment 1.

FIG. 7 is a flow chart illustrating a method of manufacturing the semiconductor device according to the embodiment 1.

FIG. 8 is a cross-sectional view of a semiconductor device according to a fourth modification example of the embodiment 1.

FIG. 9 is a cross-sectional view of a semiconductor device according to a comparative example.

FIG. 10 is a diagram illustrating a capacitance waveform of the semiconductor device.

FIG. 11 is a cross-sectional view of a semiconductor device according to an embodiment 2.

FIG. 12 is a flow chart illustrating a method of manufacturing the semiconductor device according to the embodiment 2.

### DESCRIPTION OF THE PREFERRED EMBODIMENTS

Although a first conductivity type is an n type and a second conductivity type is a p type as a conductivity type of a semiconductor layer in the description hereinafter, the conductivity type may be reversed. That is to say, the first conductivity type may be a p type, and the second conductivity type may be an n type. It is indicated that n+ has a higher n-type impurity concentration than n and n− has a lower n-type impurity concentration than n. In the similar manner in the p type, it is indicated that p+ has a higher p-type impurity concentration than p and p− has a lower p-type impurity concentration than p.

### A. Embodiment 1

### <A-1. Configuration>

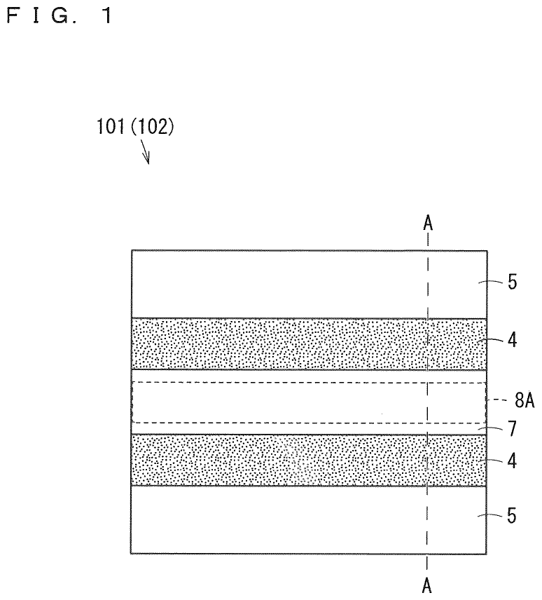

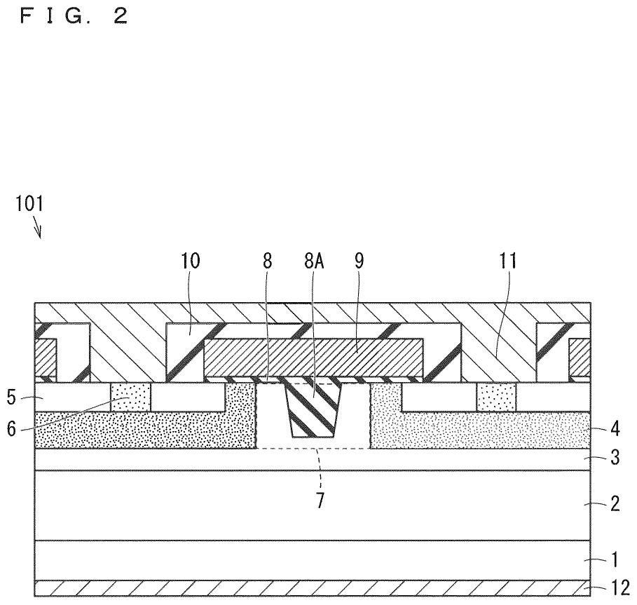

FIG. 1 is a plan view of a cell region in a semiconductor device 101 according to an embodiment 1. FIG. 2 is a cross-sectional view of the semiconductor device 101 along an A-A line in FIG. 1. In FIG. 1, a part above the semiconductor layer and a p+-type contact region 6 are omitted for convenience of description.

The cell region is a region in which a semiconductor element structure is formed to be operated as a semiconductor element. When the semiconductor device 101 is a metal-oxide-semiconductor field effect transistor (MOSFET), a MOSFET structure is formed in the cell region, and the cell region is operated as a MOSFET.

Although not illustrated in FIG. 1 and FIG. 2, the semiconductor device 101 includes a pad region and a terminal region. The pad region is a control pad controlling the MOSFET. The terminal region is a region surrounding the cell region and the pad region.

The semiconductor device 101 includes a current sensing pad or a gate pad, for example, as the control pad. The current sensing pad is a control pad detecting current flowing in the cell region. The current sensing pad is electrically connected to a part of the cell region. Accordingly, one severalth to one several-tens-thousandth of current flowing in the whole cell region flows in the current sensing pad when the current flows in the cell region. A plurality of current sensing pads may be provided, or only one current sensing pad may also be provided. The current sensing pad is also referred to as a sensing cell region. In the meanwhile, the gate pad is connected to a gate electrode 9 in the cell region, and controls current flowing in the cell region. The region in which the gate pad is formed is also referred to as a gate pad region. A cross-sectional view of the current sensing pad is also similar to that illustrated in FIG. 2. That is to say, the cell region and the current sensing pad have the same cross-sectional structure.

As illustrated in FIG. 2, the semiconductor device 101 includes an n-type semiconductor substrate 1, an n⁻-type drift layer 2, an n⁺-type well region 3, a p-type well region 4, a source region 5, a p+-type contact region 6, a gate oxide film 8, the gate electrode 9, an interlayer insulating film 10, a source electrode 11, and a drain electrode 12.

The n-type semiconductor substrate 1 is made of silicon carbide (SiC) as wide bandgap semiconductor, for example. The semiconductor device 101 is described as the MOSFET hereinafter, but may be an insulated gate bipolar transistor (IGBT), for example, in place of the MOSFET.

The n⁻-type drift layer 2 is formed on the n-type semiconductor substrate 1. The n⁺-type well region 3 is formed on the n⁻-type drift layer 2. The plurality of p-type well regions 4 are discretely formed on a surface layer of the n⁺-type well region 3. In the present specification, the n⁺-type well region 3 is also referred to as a first well region, and the p-type well region 4 is also referred to as a second well region. The source region 5 and the p+-type contact region 6 as impurity regions are provided on a surface layer of each p-type well region 4.

The n⁺-type well region 3, the n⁻-type drift layer 2, and the source region 5 are regions doped with an n-type doping. The p-type well region 4 and the p+-type contact region 6 are regions doped with a p-type doping. A carrier concentration of the n⁺-type well region 3 is higher than that of the n⁻-type drift layer 2, and a carrier concentration of the source region 5 is higher than that of the n⁺-type well region 3.

A region between two p-type well regions 4 adjacent to each other in a plan view is referred to as the JFET region 7. The surface layer of the p-type well region 4 sandwiched between the source region 5 and the n⁺-type well region 3 serves as a channel region. The gate oxide film 8 is formed on the n⁺-type well region 3 and the channel region in the JFET region 7. The gate electrode 9 is formed on the gate oxide film 8. The gate electrode 9 is formed at a position facing the channel region via the gate oxide film 8. The interlayer insulating film 10 is formed to cover the gate electrode 9.

The source electrode 11 is formed to have contact with the source region 5 and the p+-type contact region 6 via a contact hole in the interlayer insulating film 10. The drain electrode 12 is formed on a main surface of the n-type semiconductor substrate 1 on a side opposite to the n⁻⁻-type drift layer 2.

The gate oxide film 8 is formed to be thicker in the JFET region 7 than on the channel region. That is to say, the gate oxide film 8 is formed at a deeper position in the JFET region 7 than on the channel region. The gate oxide film 8 formed at the deep position is referred to as an oxide film deep portion 8A.

In the example in FIG. 1, the p-type well region 4 and the source region 5 are formed into a stripe shape. The oxide film deep portion 8A is also disposed to have a stripe shape in a center part of the JFET region 7.

A dimension of the oxide film deep portion 8A in a horizontal direction is defined as a width of the oxide film deep portion 8A, and a dimension of the oxide film deep portion 8A in a vertical direction is defined as a thickness of the oxide film deep portion 8A. The oxide film deep portion 8A has a tapered shape with a narrower width as getting closer to the drain electrode 12, that is to say, as getting deeper. Since the gate oxide film 8 is formed to be thicker in the JFET region 7 than on the channel region, parasitic capacitance can be reduced. Since the oxide film deep portion 8A has the tapered shape, a current path in a forward direction is not blocked, and increase of ON resistance is suppressed. That is to say, according to the semiconductor device 101, the parasitic capacitance can be reduced without increasing resistance.

### <A-2. Modification Example>

It is sufficient that the oxide film deep portion 8A has a shape with a narrower width as getting deeper. The shape thereof is not limited thereto illustrated in FIG. 2.

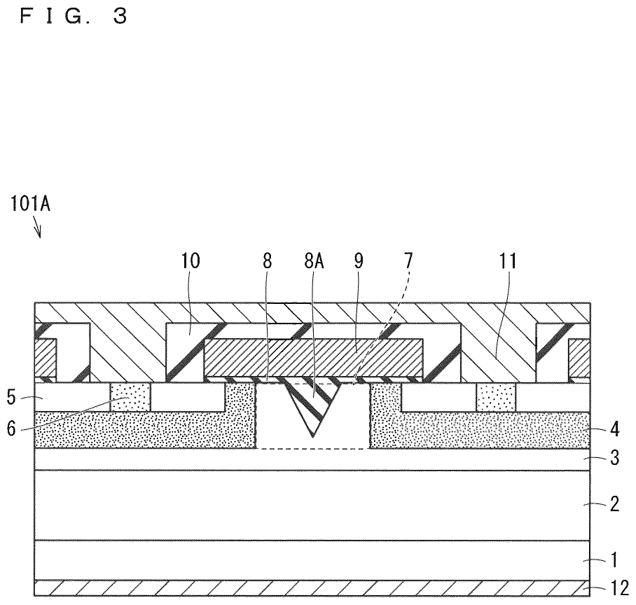

FIG. 3 is a cross-sectional view of a semiconductor device 101A according to a first modification example of the embodiment 1. As illustrated in FIG. 3, the oxide film deep portion 8A may have a triangular shape in a cross-sectional view as illustrated in FIG. 3.

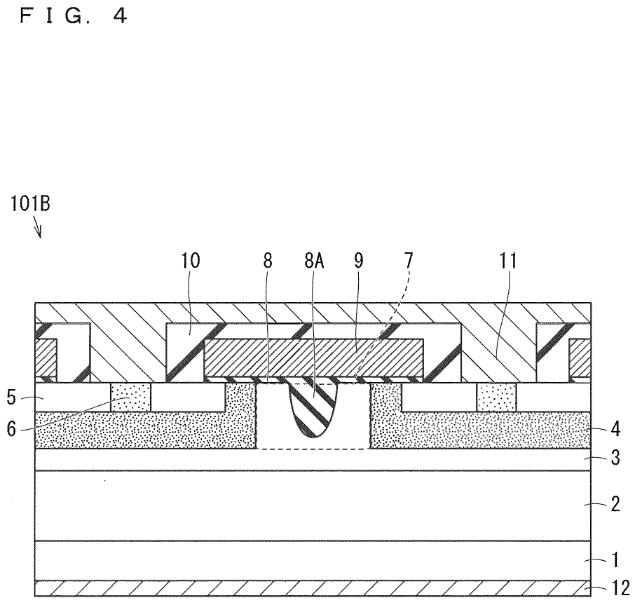

FIG. 4 is a cross-sectional view of a semiconductor device 101B according to a second modification example of the embodiment 1. As illustrated in FIG. 4, the oxide film deep portion 8A may have a curved outline in a cross-sectional view of the oxide film deep portion 8A as illustrated in FIG. 4.

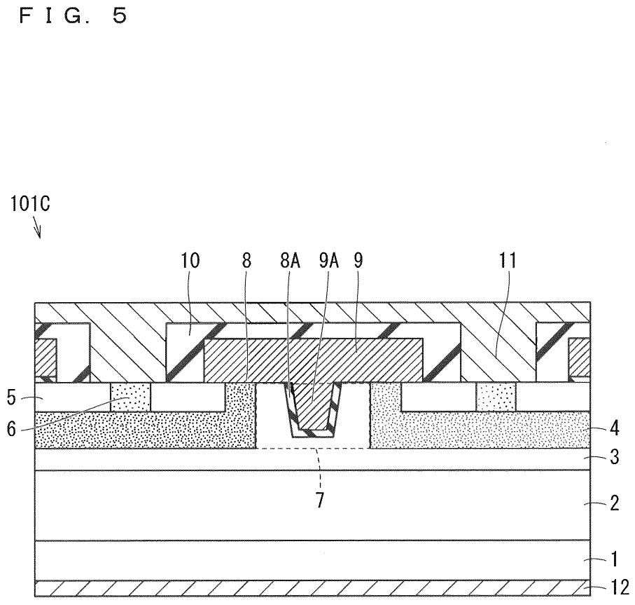

FIG. 5 is a cross-sectional view of a semiconductor device 101C according to a third modification example of the embodiment 1. As illustrated in FIG. 5, the gate electrode 9 may include a gate electrode deep portion 9A formed on the channel region and the JFET region 7 via the gate oxide film 8 and buried in the oxide film deep portion 8A. The gate electrode deep portion 9A is a part formed at a deeper position than a surface of the channel region on the oxide film deep portion 8A. The gate electrode deep portion 9A may have a tapered shape with a narrower width as getting deeper.

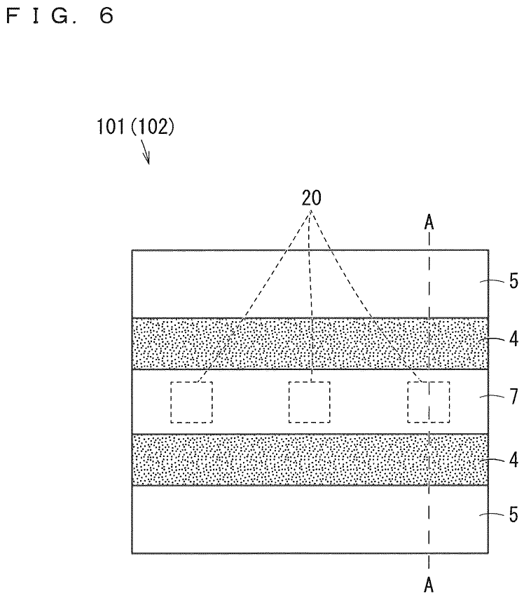

In the example in FIG. 1, the oxide film deep portion 8A is disposed to have a stripe shape in a center part of the JFET region 7. However, as illustrated in FIG. 6, the oxide film deep portion 8A may be periodically disposed in the center part of the JFET region 7. The parasitic capacitance can be thereby adjusted. The oxide film deep portion 8A may not be periodically disposed as long as the plurality of oxide film deep portions 8A are discretely formed in one JFET region 7.

FIG. 1 and FIG. 6 illustrate the example of the MOSFET disposed to have the stripe shape. However, the MOSFET may be disposed to have the other shape such as a lattice shape or a hexagonal shape. In any shape, the oxide film deep portion 8A is formed in the JFET region 7.

### <A-3. Manufacturing Process>

A method of manufacturing the semiconductor device 101 is described. The n-type semiconductor substrate 1 is prepared in Step S101.

Next, in Step S102, the n⁻-type drift layer 2 is formed by epitaxial growth by a chemical vapor deposition (CVD) method, for example, on a main surface of the n-type semiconductor substrate 1.

Subsequently, in Step S103, an implantation mask is formed by a photoresist and N, for example, is ion-implanted into a surface of the n⁻-type drift layer 2 by implantation, for example. Subsequently, the implantation mask is removed. A region in which n-type ions are ion-implanted by the present process serves as the n⁺-type well region 3.

The implantation mask is formed by photoresist, and Al, for example, as a p-type impurity is ion-implanted into the n⁺-type well region 3, for example. Subsequently, the implantation mask is removed. A region in which p-type ions are ion-implanted by the present process serves as the p-type well region 4.

Furthermore, the implantation mask is formed by photoresist, and N, for example, as an n-type impurity is ion-implanted into the p-type well region 4, for example. Subsequently, the implantation mask is removed. A region in which n-type ions are ion-implanted by the present process serves as the source region 5.

Next, in Step S104, annealing is performed in inert gas atmosphere such as argon (Ar) gas by a heat treatment apparatus. An annealing temperature is equal to or larger than 1300 °C and equal to or smaller than 1900 °C, and an annealing time is equal to or larger than 30 seconds and equal to or smaller than one hour. The ion-implanted N and Al are electrically activated by the annealing.

Subsequently, in Step S105, a groove is formed to be located at a center of the JFET region 7 using dry etching, for example.

Next, in Step S106, the gate oxide film 8 having desired thickness is formed on a surface of semiconductor by heat oxidation, for example. At this time, a speed of oxidation is high at a groove part by characteristics of the n-type semiconductor substrate 1, and a film thickness of the oxide film deep portion 8A as the gate oxide film 8 at the groove part is resultingly formed to be thicker than the other part.

Subsequently, in Step S107, a polycrystalline silicon film having conductivity is formed on the gate oxide film 8 by a low pressure CVD method, and is patterned to form the gate electrode 9. Subsequently, the interlayer insulating film 10 is formed by a low pressure CVD method. Formed subsequently is a contact hole passing through the interlayer insulating film 10 and the gate oxide film 8 to reach the source region 5 and the p+-type contact region 6 in a unit cell.

Next, in Step S108, a heat treatment is performed at a temperature equal to or larger than 600 °C and equal to or smaller than 1100 °C after a metal film made of Ni as a main component is formed by a sputtering method, for example, and the metal film made of Ni as the main component and the semiconductor layer in the contact hole are reacted to form silicide between the semiconductor layer and the metal film. Subsequently, the metal film remaining on the interlayer insulating film 10 other than silicide made by reaction is removed by wet etching. An ohmic electrode is thereby formed.

Furthermore, metal made of Ni as a main component is formed on a back surface as a main surface of the n-type semiconductor substrate 1 on a side opposite to the n⁻-type drift layer 2, and a heat treatment is performed thereon to form an ohmic electrode.

Subsequently, in Step S109, wiring metal made of Al, for example, is formed on the surface of the n-type semiconductor substrate 1 which has been processed by a sputtering method or a vapor deposition method, and is processed into a predetermined shape by a photolithography technique to form the source electrode 11 having contact with the ohmic electrode and the gate wiring having contact with the gate electrode 9. Furthermore, the drain electrode 12 as a metal film is formed on a surface of the ohmic electrode formed on the back surface of the semiconductor substrate.

### <A-4. Effect>

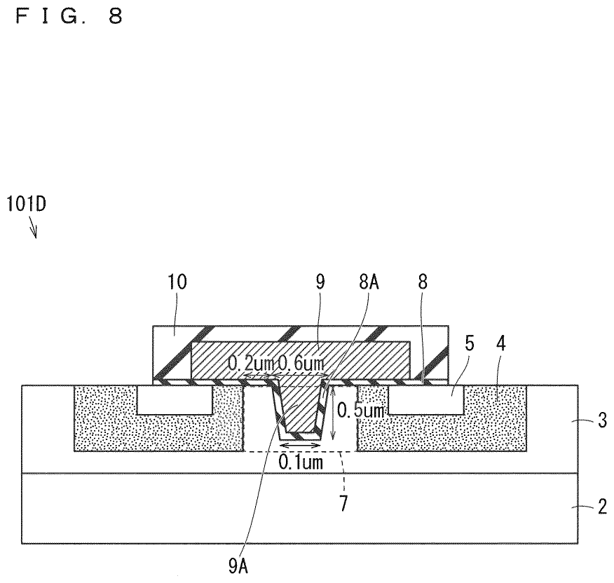

FIG. 8 is a cross-sectional view of a semiconductor device 101D according to a fourth modification example of the embodiment 1. The semiconductor device 101D is different from the semiconductor device 101C according to the third modification example of the embodiment 1 in that the semiconductor device 101D does not include the p+-type contact region 6. In FIG. 8, illustration of the n-type semiconductor substrate 1, the source electrode 11, and the drain electrode 12 is omitted.

A distance from an uppermost part of the oxide film deep portion 8A to the p-type well region 4 is 0.2 μm in the semiconductor device 101D. A width of the uppermost part of the oxide film deep portion 8A is 0.6 μm. A width of a deepest part of the oxide film deep portion 8A is 0.1 μm. A height of the oxide film deep portion 8A is 0.5 μm.

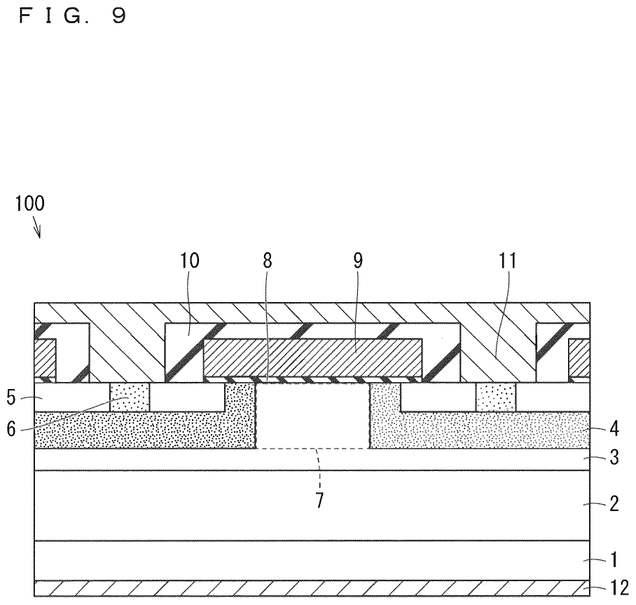

FIG. 9 is a cross-sectional view of a semiconductor device 100 according to a comparative example. The semiconductor device 100 is different from the semiconductor device 101 according to the embodiment 1 in that the gate oxide film 8 does not include the oxide film deep portion 8A in the JFET region 7.

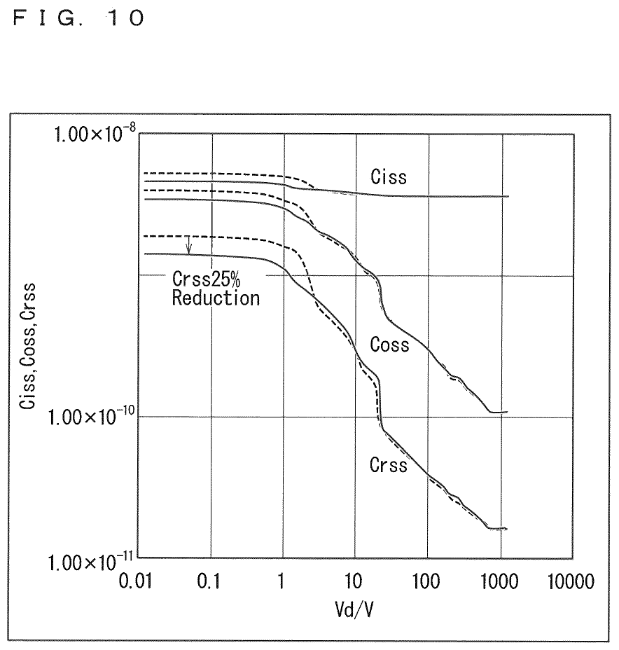

FIG. 10 illustrates a capacitance waveform of the semiconductor device 101D (hereinafter, “the present structure”) according to the fourth modification example of the embodiment 1 and the semiconductor device 100 (hereinafter, “the conventional structure”) according to the comparative example. A lateral axis in FIG. 10 expresses Vd/V, and a vertical axis indicates input capacitance Ciss, output capacitance Coss, and reverse transfer capacitance Crss. Vd/V is obtained by normalizing drain voltage by reference voltage V.

FIG. 10 shows that reverse transfer capacitance Crss is reduced by approximately 25% in the present structure compared with the conventional structure. That is to say, since the gate oxide film 8 is formed to be thicker in the JFET region 7 than on the channel region in the present structure, parasitic capacitance can be reduced compared with the conventional structure. The oxide film deep portion 8A has the tapered shape with the narrower width as getting deeper in the present structure, thus does not have influence on ON resistance, and ON resistance in the present structure is equal to that according to the comparative example.

A bottom surface of the oxide film deep portion 8A is located above a bottom surface of the p-type well region 4 in FIG. 2 to 5 and 8. Accordingly, ON resistance can be reduced.

However, the bottom surface of the oxide film deep portion 8A may be located below the bottom surface of the p-type well region 4. As the bottom surface of the oxide film deep portion 8A gets closer to a lower side, parasitic capacitance is reduced, and switching characteristics are improved. Although ON resistance is increased instead, the oxide film deep portion 8A has the tapered shape with the narrower width as getting deeper. Thus, increase of ON resistance can be minimized.

### B. Embodiment 2

### <B-1. Configuration>

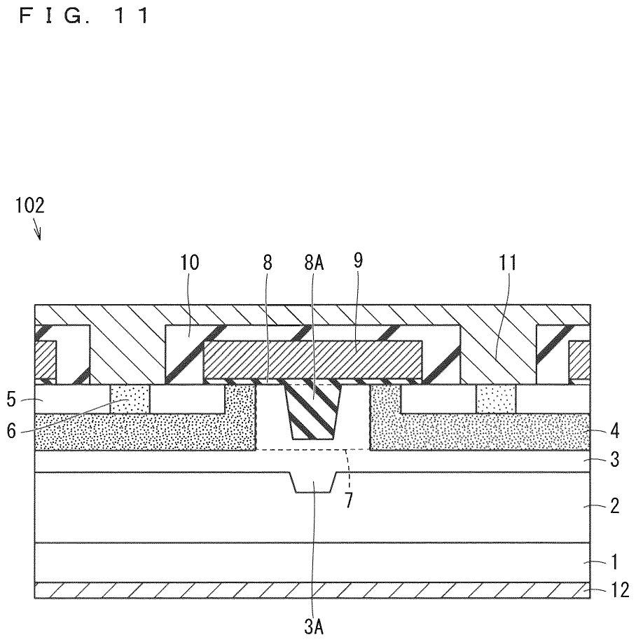

FIG. 11 is a cross-sectional view of a semiconductor device 102 according to an embodiment 2. A top view of the semiconductor device 102 is similar to that of the semiconductor device 101 according to the embodiment 1 illustrated in FIG. 1 or FIG. 6.

The semiconductor device 102 is different from the semiconductor device 101 according to the embodiment 1 in that the n⁺-type well region 3 includes a deep well region deep portion 3A immediately below the oxide film deep portion 8A of the gate oxide film 8. The well region deep portion 3A is formed at a deeper position than the n⁺-type well region 3 formed in the region other than the region immediately below the oxide film deep portion 8A.

According to the semiconductor device 102, ON resistance can be reduced by the well region deep portion 3A compared with the semiconductor device 101 according to the embodiment 1.

In the manner similar to the oxide film deep portion 8A, the well region deep portion 3A also has the tapered shape with the narrower width as getting deeper as illustrated in FIG. 11.

### <B-2. Manufacturing Process

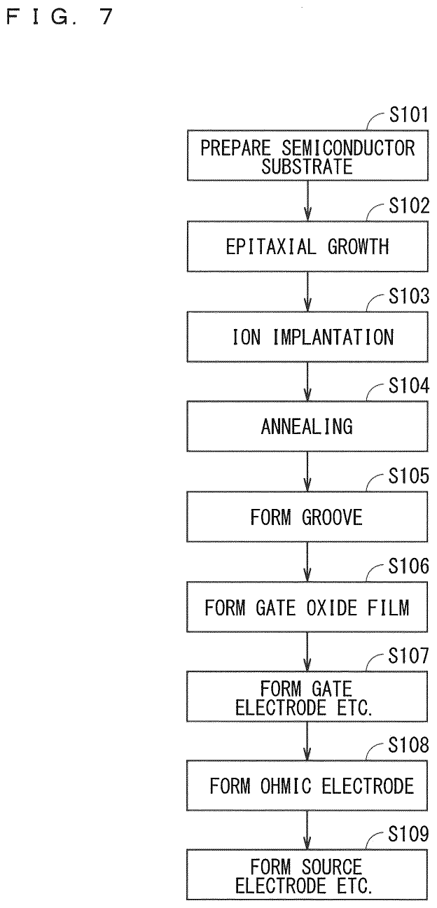

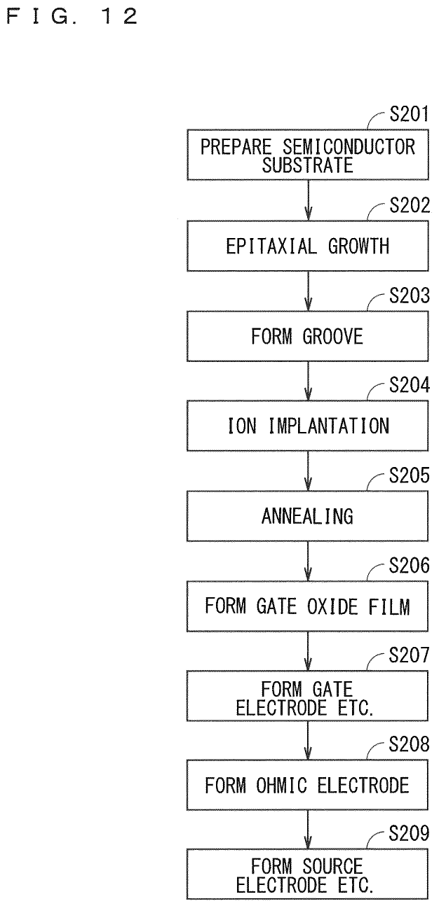

FIG. 12 is a flow chart illustrating a method of manufacturing the semiconductor device 102 according to the embodiment 2. Steps S201 and S202 are similar to Steps S101 and S102 in FIG. 7.

A groove is formed in a region of the n⁻-type drift layer 2 which is to be the JFET region 7 in Step S203 before the ion implantation is performed after the n⁻-type drift layer 2 is formed.

After the groove is formed, in Step S204, an implantation mask is formed by a photoresist, and N, for example, is ion-implanted into the surface of the n⁻-type drift layer 2 by implantation, for example. Subsequently, the implantation mask is removed. A region in which n-type ions are ion-implanted by the present process serves as the n⁺-type well region 3. Since the ion implantation is performed also on a part where the groove is formed in the present process, ions are deeply implanted below the groove, and a region where the ions are deeply implanted serves as the well region deep portion 3A.

The subsequent Steps S205, S206, S207, S208, and S209 are similar to Steps S104, S106, S107, S108, and S109 in FIG. 7.

### <B-3. Effect>

The semiconductor device 102 includes the oxide film deep portion 8A in the JFET region 7 as the gate oxide film 8 deeper than the gate oxide film 8 on the channel region in the manner similar to the semiconductor device 101 according to the embodiment 1, and the oxide film deep portion 8A has the tapered shape having the narrower width as getting deeper. Accordingly, according to the semiconductor device 102, ON resistance and parasitic capacitance can be reduced in the manner similar to the semiconductor device 101.

While the embodiments etc. have been shown and described in detail, the above embodiments are not restrictive. Various modifications and replacements can be added to the above embodiments without departing from the scope of claims.

The aspects of the present disclosure are collectively described hereinafter as appendixes.

### (Appendix 1)

A semiconductor device, comprising:

a drift layer of a first conductivity type formed on a semiconductor substrate of a first conductivity type;

a first well region formed on the drift layer and having a higher impurity concentration of a first conductivity type than the drift layer;

a plurality of second well regions of a second conductivity type discretely formed on a surface layer of the first well region;

an impurity region of a first conductivity type formed on a surface layer of each of the plurality of second well regions;

a gate oxide film formed on a first well region in a JFET region as a region sandwiched between the plurality of second well regions in a plan view and a channel region as a region sandwiched between the JFET region and the impurity region in the surface layer of each of the second well regions; and

a gate electrode formed on the channel region via the gate oxide film, wherein

the gate oxide film includes at least one oxide film deep portion formed at a deeper position than the gate oxide film on the channel region in the JFET region, and

the oxide film deep portion has a tapered shape with a narrower width as getting deeper.

### (Appendix 2)

The semiconductor device according to Appendix 1, wherein

the gate electrode is formed on the channel region and the JFET region via the gate oxide film,

the gate electrode includes a gate electrode deep portion as a part formed at a deeper position than a surface of the channel region on the oxide film deep portion, and

the gate electrode deep portion has a tapered shape with a narrower width as getting deeper.

### (Appendix 3)

The semiconductor device according to Appendix 1 or 2, wherein

the first well region includes a first well region deep portion formed at a deeper position than another part immediately below the JFET region, and

the first well region deep portion has a tapered shape with a narrower width as getting deeper.

### (Appendix 4)

The semiconductor device according to any one of Appendixes 1 to 3, wherein

a bottom surface of the oxide film deep portion is located above a bottom surface of each of the second well regions.

### (Appendix 5)

The semiconductor device according to any one of Appendixes 1 to 3, wherein

a bottom surface of the oxide film deep portion is located below a bottom surface of each of the second well regions.

### (Appendix 6)

The semiconductor device according to any one of Appendixes 1 to 5, wherein

the plurality of oxide film deep portions are discretely formed for the one JFET region.

### (Appendix 7)

The semiconductor device according to any one of Appendixes 1 to 6, wherein

the semiconductor substrate is a silicon carbide semiconductor substrate.

### (Appendix 8)

A method of manufacturing a semiconductor device, comprising:

forming a drift layer of a first conductivity type on a semiconductor substrate of a first conductivity type;

forming a first well region having a higher impurity concentration of a first conductivity type than the drift layer on a surface layer of the drift layer;

discretely forming a plurality of second well regions of a second conductivity type on a surface layer of the first well region;

forming an impurity region of a first conductivity type on a surface layer of each of the plurality of second well regions;

forming a gate oxide film in a JFET region as a region sandwiched between the plurality of second well regions in a plan view in the first well region and a channel region as a region sandwiched between the JFET region and the impurity region in the surface layer of each of the second well regions;

forming a gate electrode on the channel region via the gate oxide film;

forming a groove in the JFET region before the gate oxide film is formed; and

forming the gate oxide film inside the groove in the JFET region.

### (Appendix 9)

The method of manufacturing the semiconductor device according to Appendix 8, wherein

the groove has a narrower width as getting deeper.

### (Appendix 10)

The method of manufacturing the semiconductor device according to Appendix 8 or 9, wherein

a bottom surface of the groove is located above a bottom surface of each of the second well regions.

### (Appendix 11)

The method of manufacturing the semiconductor device according to Appendix 8 or 9, wherein

a bottom surface of the groove is located below a bottom surface of each of the second well regions.

### (Appendix 12)

The method of manufacturing the semiconductor device according to any one of Appendixes 8 to 11, wherein

the groove is formed prior to the first well region.

### (Appendix 13)

The method of manufacturing the semiconductor device according to any one of Appendixes 8 to 11, wherein

the groove is formed after the first well region.

While the disclosure has been shown and described in detail, the foregoing description is in all aspects illustrative and not restrictive. It is therefore understood that numerous modifications and variations can be devised.

What is claimed is:

1. A semiconductor device, comprising:
a drift layer of a first conductivity type formed on a semiconductor substrate of a first conductivity type;
a first well region formed on the drift layer and having a higher impurity concentration of a first conductivity type than the drift layer;
a plurality of second well regions of a second conductivity type discretely formed on a surface layer of the first well region;
an impurity region of a first conductivity type formed on a surface layer of each of the plurality of second well regions;
a gate oxide film formed on a first well region in a JFET region as a region sandwiched between the plurality of second well regions in a plan view and a channel region as a region sandwiched between the JFET region and the impurity region in the surface layer of each of the second well regions; and
a gate electrode formed on the channel region via the gate oxide film, wherein the gate oxide film includes at least one oxide film deep portion formed at a deeper position than the gate oxide film on the channel region in the JFET region, and
the oxide film deep portion has a tapered shape with a narrower width as getting deeper.

2. The semiconductor device according to claim 1, wherein
the gate electrode is formed on the channel region and the JFET region via the gate oxide film,
the gate electrode includes a gate electrode deep portion as a part formed at a deeper position than a surface of the channel region on the oxide film deep portion, and
the gate electrode deep portion has a tapered shape with a narrower width as getting deeper.

3. The semiconductor device according to claim 1, wherein
the first well region includes a first well region deep portion formed at a deeper position than another part immediately below the JFET region, and
the first well region deep portion has a tapered shape with a narrower width as getting deeper.

4. The semiconductor device according to claim 1, wherein
a bottom surface of the oxide film deep portion is located above a bottom surface of each of the second well regions.

5. The semiconductor device according to claim 1, wherein
a bottom surface of the oxide film deep portion is located below a bottom surface of each of the second well regions.

6. The semiconductor device according to claim 1, wherein
the plurality of oxide film deep portions are discretely formed for the one JFET region.

7. The semiconductor device according to claim 1, wherein
the semiconductor substrate is a silicon carbide semiconductor substrate.

8. A method of manufacturing a semiconductor device, comprising:
forming a drift layer of a first conductivity type on a semiconductor substrate of a first conductivity type;
forming a first well region having a higher impurity concentration of a first conductivity type than the drift layer on a surface layer of the drift layer;
discretely forming a plurality of second well regions of a second conductivity type on a surface layer of the first well region;
forming an impurity region of a first conductivity type on a surface layer of each of the plurality of second well regions;
forming a gate oxide film in a JFET region as a region sandwiched between the plurality of second well regions in a plan view in the first well region and a channel region as a region sandwiched between the JFET region and the impurity region in the surface layer of each of the second well regions;
forming a gate electrode on the channel region via the gate oxide film;
forming a groove in the JFET region before the gate oxide film is formed; and
forming the gate oxide film inside the groove in the JFET region.

9. The method of manufacturing the semiconductor device according to claim 8, wherein
the groove has a narrower width as getting deeper.

10. The method of manufacturing the semiconductor device according to claim 8, wherein
a bottom surface of the groove is located above a bottom surface of each of the second well regions.

11. The method of manufacturing the semiconductor device according to claim 8, wherein
a bottom surface of the groove is located below a bottom surface of each of the second well regions.

12. The method of manufacturing the semiconductor device according to claim 8, wherein
the groove is formed prior to the first well region.

13. The method of manufacturing the semiconductor device according to claim 8, wherein
the groove is formed after the first well region.
